(19) United States
(12) Patent Application Publication
(10) Pub. No.: US 2006/0080053 A1
(43) Pub. Date: Apr. 13, 2006

(54) Method of measuring unnecessary electromagnetic radiation, apparatus and system for measuring unnecessary electromagnetic radiation

(76) Inventors: Makoto Torigoe, Okayama (JP); Takashi Suga, Yokohama (JP)

Correspondence Address: MATTINGLY, STANGER, MALUR & BRUNDIDGE, P.C., 1800 DIAGONAL ROAD, SUITE 370, ALEXANDRIA, VA, 22314, US

(21) Appl. No.: 11/227,139

(22) Filed: Sep. 16, 2005

(30) Foreign Application Priority Data
Sep. 29, 2004 (JP) 2004-283019

(51) Int. Cl. G01R 19/00

(52) U.S. Cl. 702/64

(57) ABSTRACT

According to the present invention, unnecessary electromagnetic radiation from the hard disk alone is measured by connecting one end of a hard disk drive which has an interface cable and a power cable extending out from the other end thereof to a conductive jig extended along the extension direction of these cables; configuring a coaxial-structured transmission line with the jig, the hard disk drive and the cables which are arranged in this order along the extension direction of the cables and a hollow conductive enclosure covering the jig, the hard disk drive and the cables; and measuring common-mode current flowing through the interface cable and the power cable and potential of the conductive enclosure at the same.

The present application claims priority from Japanese application JP2004-283019 filed on Sep. 29, 2004, the content of which is hereby incorporated by reference into this application.

### BACKGROUND OF THE INVENTION

1. Field of the Invention

The present invention relates to a technique for measuring a level of unnecessary electromagnetic radiation (also described as “Electromagnetic Interference (EMI)” generated thereby) including a hard disk.

2. Description of the Related Art

At present, information technology equipment is regulated as to unnecessary electromagnetic waves radiated therefrom. For example, Federal Communication Commission (FCC) in the US and Voluntary Control Council for Information Technology Equipment (VCCI) in Japan regulate unnecessary electromagnetic radiation from information technology equipment. These regulations stipulate that an electric field occurring from the whole of the information technology apparatus under measurement be measured at a position 3 m or 10 m away, and regulate electric field strength thereof.

These regulations regulate the electric field that occurs from the whole of the information technology apparatus, but do not regulate components alone such as a hard disk drive etc. used therein.

As a method for measuring unnecessary electromagnetic radiation, there is a method employing a radio wave anechoic chamber such as described in patent document 1.

[Patent document 1] Japanese Unexamined Patent Publication No. 2002-064294

### SUMMARY OF THE INVENTION

In many cases, hard disk drives are easily available as single items as well at ordinary electrical appliance stores, so that users can freely replace hard disk drives or install additional ones.

Therefore, from now on, there is required a technique for measuring the level of unnecessary electromagnetic radiation at the level of components that can be accessed by users such as hard disk drives used in apparatuses.

A hard disk drive does not operate alone and requires a peripheral device for reading and writing the drive.

For this reason, it is difficult to accurately evaluate the level of unnecessary electromagnetic radiation of the hard disk drive alone as an electric field at a distance of 3 m or 10 m in the same way as in information technology equipment using a radio wave anechoic chamber such as described in patent document 1, due to the influence of unnecessary electromagnetic radiation occurring from the peripheral device for reading and writing the hard disk drive.

Further, there is an effort underway to evaluate unnecessary electromagnetic radiation by common-mode current flowing through the power cable of the hard disk drive. However, in reality, its evaluation result does not necessarily coincide with the measurement result of unnecessary electromagnetic radiation in the case of actually mounting the hard disk drive in an information technology apparatus.

This may be because the way of installing an enclosure in the case of mounting the hard disk drive in the information technology apparatus is different from that in the case of measuring with the hard disk drive alone so that the actual current routes are different.

Further, a Work Bench Faraday Cage and a TEM Cell (a chamber having a similar shape to the coaxial waveguide and generating Transverse ElectroMagnetic wave therein) are employed as apparatuses for evaluating unnecessary electromagnetic radiation of LSI alone. However, these apparatuses are structurally specialized in measuring high-frequency components of the power current of LSI and cannot be used for the hard disk drive having an interface cable etc.

It is an object of the present invention to provide a technique for measuring unnecessary electromagnetic radiation occurring from a hard disk drive with high accuracy.

As a typical method of the invention which can solve the above problem, there is provided a method of measuring unnecessary electromagnetic radiation using a hollow conductive chassis, in a state where an interface cable and a power cable that are connected to a hard disk are routed outside the conductive chassis and the hard disk is fixed to the conductive chassis through the use of an insulating member. The method includes, in a state of applying a predetermined signal (or a specified signal) to wiring or a component in the hard disk, measuring common-mode current flowing through the interface cable and the power cable of the hard disk and potential of an enclosure of the hard disk.

According to the method, the interface cable and the power cable that are connected to the hard disk are routed outside the conductive chassis, thereby greatly reducing the influence of unnecessary electromagnetic radiation occurring from the peripheral device for reading and writing the hard disk drive.

As a structure appropriate to employ the method, there is provided an apparatus for measuring unnecessary electromagnetic radiation. The apparatus includes a conductive chassis, a conductive setting jig for installing a hard disk drive in the chassis, a power cable and an interface cable that are connected to the hard disk drive, and a coaxial connector connected to an end of the conductive chassis, wherein an outer conductor of the coaxial connector is connected to the chassis, an inner conductor of the coaxial connector is connected to the setting jig, and the setting jig is constructed to be electrically connected to an enclosure of the hard disk drive to be measured, thereby forming a transmission line structure between the hard disk drive and the chassis.

Forming the above-mentioned transmission line structure enables the energy of unnecessary electromagnetic radiation to be efficiently transmitted to a measuring instrument.

According to the present invention, it is possible to measure unnecessary electromagnetic radiation occurring from a hard disk drive with high accuracy.

### BRIEF DESCRIPTION OF THE DRAWINGS

FIG. 1 is a perspective view showing the internal structure in the case where a hard disk is installed in an unnecessary electromagnetic radiation measuring apparatus;

FIG. 2 is a cross sectional view of a setting jig 102 of the unnecessary electromagnetic radiation measuring apparatus shown in FIG. 1;

FIG. 3 is a longitudinal sectional view of a setting jig 102 of the unnecessary electromagnetic radiation measuring apparatus shown in FIG. 1;

FIG. 4 is an explanatory drawing showing a measurement method employing the unnecessary electromagnetic radiation measuring apparatus shown in FIG. 1; and

FIG. 5 is an illustration of a measurement system employing the unnecessary electromagnetic radiation measuring apparatus shown in FIG. 1.

### DETAILED DESCRIPTION

Embodiments of the present invention will be described below with reference to the accompanying drawings.

FIG. 1 is a perspective view showing the internal structure in the case where a hard disk is installed in an unnecessary electromagnetic radiation measuring apparatus.

A chassis 103 is rendered transparent in the figures, for convenience in describing the internal structure.

An unnecessary electromagnetic radiation measuring apparatus of this embodiment includes a setting jig 102 having a structure capable of installing and removing a hard disk drive 101, a long slender (or elongate) chassis 103 that fixes the setting jig 102, a coaxial connector 104 that is provided at one end in the longitudinal direction of the chassis 103, an interface cable 105 for connecting the hard disk drive with a peripheral device, and a power cable 106 for supplying power to the hard disk drive 101.

In this embodiment, the long slender hard disk drive 101 is installed in the direction of the stretch of the interface cable 105 and the power cable 106.

The setting jig 102 can fix a long slender structure extending in the direction of the stretch (or the extension direction) of the cables (the interface cable 105 and the power cable 106) of the hard disk drive 101. More specifically, the structure of the setting jig enables the hard disk to be fixed in such a direction that the side of the hard disk from which the cables (the interface cable 105 and the power cable 106) come out faces the end of the chassis 103 remote from the coaxial connector 104.

The chassis 103 is provided with a for-taking-out window 107 that is necessary to install the hard disk drive 101.

Further, the long slender chassis 103 tapers down, in the direction of the length, namely, toward the coaxial connector 104, and the space between the setting jig 102 and the chassis 103 becomes narrow toward the coaxial connector 104. The structure of the chassis 103 and the setting jig 102 enables a transmission line with an approximately 50-Ω (45 to 50 Ω) impedance, and therefore can achieve impedance matching.

In the case where the cables 105 and 106 of the hard disk drive 101 are routed (or extended) along the direction of the length from one of the short sides of the hard disk drive 101, the chassis 103 and the setting jig 102 provided within the hollow are constructed as follows. The coaxial connector 104 is provided at the end of the chassis 103 that faces the other short side of the hard disk drive 101. The chassis 103 and the setting jig 102 taper down in such a manner that the space between the chassis 103 and the setting jig 102 becomes gradually narrow toward the end of the chassis 103 where the coaxial connector 104 is provided. The setting jig 102 fixes the hard disk drive, with the setting jig being arranged such that the end located opposite from the end of the chassis 103 where the coaxial connector 104 is provided faces the cables 105 and 106 of the hard disk drive 101.

That is, the setting jig 102 is arranged such that the other end opposite from the one end where the coaxial connector 104 is provided faces the cables 105 and 106.

The interface cable 105 and the power cable 106 are routed outside the chassis through an opening provided at an end of the chassis 103. Further, it is possible to provide a connector instead of the opening at the end of the chassis 103 and transmit a signal outside the chassis through the connector.

These cables (the interface cable and the power cable) are routed (or extended) nearly straight to the chassis opening or connector.

Thus, since the structure of the chassis 103 and the setting jig 102 achieves impedance matching, energy of unnecessary electromagnetic radiation occurring from the hard disk can be efficiently transmitted to a measuring instrument.

The end of the setting jig 102 adjacent to the coaxial connector 104 is connected to the core wire of the coaxial connector, and the end of the chassis 103 adjacent to the coaxial connector 104 is connected to the outer conductor of the coaxial connector 104.

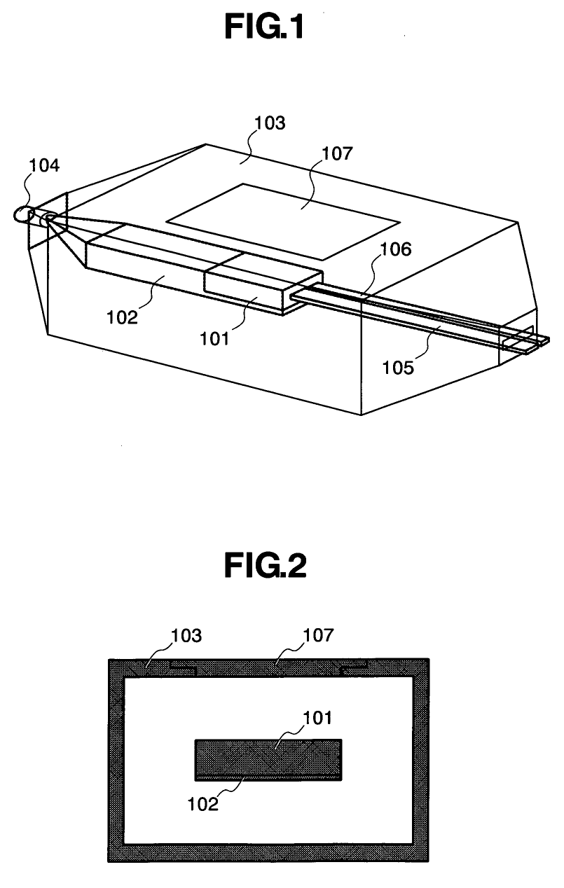

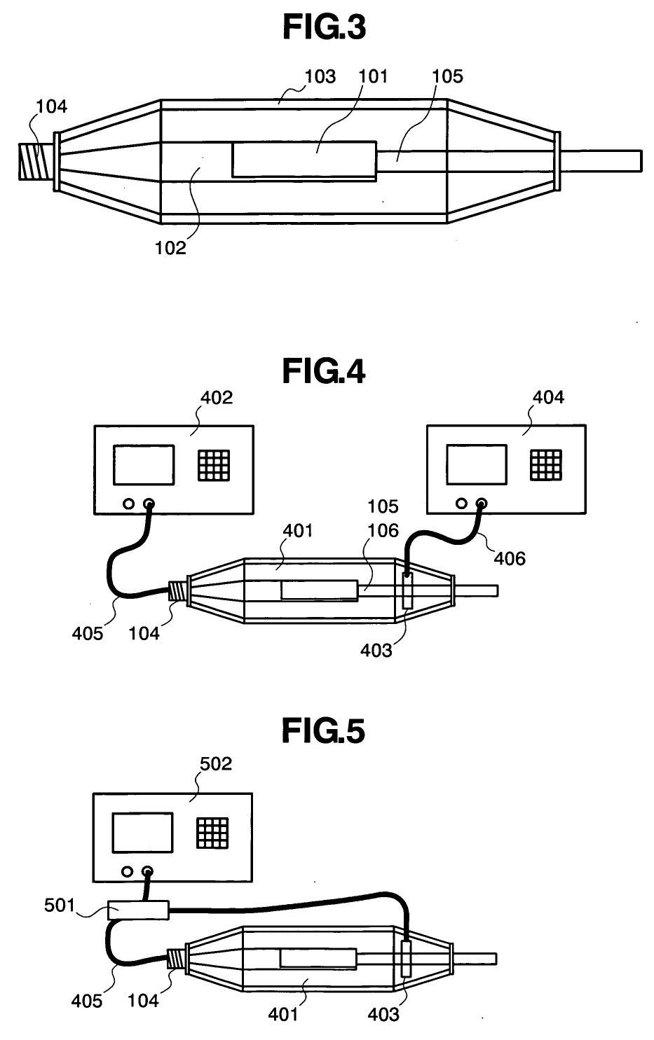

FIG. 2 is a cross sectional view of the unnecessary electromagnetic radiation measuring apparatus shown in FIG. 1. FIG. 3 is a longitudinal sectional view of the unnecessary electromagnetic radiation measuring apparatus shown in FIG. 1.

In the sectional views, there is constructed a transmission line in which the hard disk drive 101 and the setting jig 102 are a core wire and the chassis 103 is an outer conductor.

The dimensions of the cross section of the hard disk drive 101 are 25.4 mm×101.6 mm in the case of a 3.5-inch hard disk drive. The inside dimensions of the cross section of the chassis 103 are 119 mm×195 mm. In this embodiment, the chassis 103 of the above dimensions has been adopted. However, the present invention is not limited to the above dimensions, and it is possible to adopt a shape that forms an impedance of approximately 50 Ω (45 to 50 Ω). However, in the case where the distances between an end face of the hard disk drive 101 and the chassis 103 vary greatly by location, the unevenness of electromagnetic field becomes large and the measurement accuracy may be reduced. Therefore, it is preferable that the distances between the end faces of the hard disk drive 101 and the chassis 103 of the surroundings be roughly even.

The hard disk drive 101 is connected to the setting jig 102 using conductive screws, the potential of the enclosure of the hard disk drive is electrically connected to the setting jig. It is preferable that at least one of the plurality of screws be made of metal.

FIG. 4 shows a measurement system employing the unnecessary electromagnetic radiation measuring apparatus shown in FIG. 1.

The measurement system includes the above-described unnecessary electromagnetic radiation measuring apparatus 401, a first spectrum analyzer 402, a current probe 403, and a second spectrum analyzer 404.

The second spectrum analyzer 404 and the current probe 403 are connected to a coaxial cable 406 in order to measure current flowing through the interface cable 105 and the power cable 106.

The current probe 403 may be inserted from the outside through the chassis opening or may be connected beforehand to the connector mounted on the chassis. In order to measure the current flowing through the interface cable 105 and the power cable 106, these cables coming out from the hard disk drive 101 are arranged such that they pass through the loop of the probe.

Since the coaxial connector 104 of the unnecessary electromagnetic radiation measuring apparatus 401 is connected to the spectrum analyzer 402 using a coaxial cable 405, the spectrum analyzer 402 can measure the potential of the enclosure of the hard disk drive.

A signal detected by the current probe 403 is transmitted to the spectrum analyzer 404 through the coaxial cable 406. The spectrum analyzer 404 can measure high-frequency common-mode current flowing through the interface cable 105 and the power cable 106.

Thus, in the state where the interface cable and the power cable connected to the hard disk are routed (or extended) outside the conductive chassis and the hard disk is fixed to the chassis through the use of an insulating member and in the state of applying a predetermined signal (or a specified signal) to the wiring or the components in the hard disk, it is possible to measure the common-mode current flowing through the interface cable and the power cable of the hard disk and the potential of the enclosure of the hard disk.

Further, it is possible to measure substantially at the same time, the common-mode current flowing through the interface cable and the power cable of the hard disk drive and the potential of the enclosure.

Further, if an operator sets again the state of applying the predetermined signal to the wiring or the components in the hard disk, it is possible to shift timing for measuring the common-mode current from timing for measuring the potential of the enclosure of the hard disk, as a matter of course.

To be more specific, the operator measures one of the common-mode current and the potential of the enclosure of the hard disk, then changes the state of applying the predetermined signal to the wiring or the components in the hard disk, then sets again the state of applying the predetermined signal to the wiring or the components in the hard disk, and then measures the other of the common-mode current and the potential of the enclosure of the hard disk.

FIG. 5 shows a measurement system employing the unnecessary electromagnetic radiation measuring apparatus shown in FIG. 1, which differs from the measurement system of FIG. 4.

In the example shown in FIG. 4, two spectrum analyzers are used. However, one spectrum analyzer 502 is used in this measurement system.

The coaxial connector 104 of the unnecessary electromagnetic radiation measuring apparatus 401 is connected to the spectrum analyzer 502 through a high-frequency switch 501 using the coaxial cable 405.

The current probe 403 is connected to the spectrum analyzer 502 through the high-frequency switch 501 using a coaxial cable.

The high-frequency switch 501 transmits the potential transmitted from the coaxial connector 104 and the current detected by the current probe 403 flowing through the interface cable 105 and the power cable 106 to the spectrum analyzer 502, performing high-frequency switching by turns.

Thus, the use of the high-frequency switch 501 enables the single spectrum analyzer 502 to measure unnecessary electromagnetic radiation. Further, needless to say, this measurement has to be performed in the state of applying the predetermined signal to the wiring or the components in the hard disk.

While we have shown and described several embodiments in accordance with the present invention, it is understood that the same is not limited thereto but is susceptible of numerous changes and modifications as known to those skilled in the art, and we therefore do not wish to be limited to the details shown and described herein but intend to cover all such changes and modifications as are encompassed by the scope of the appended claims.

What is claimed is:

1. A method of measuring unnecessary electromagnetic radiation using a hollow conductive chassis, in a state where an interface cable and a power cable that are connected to a hard disk are routed outside the conductive chassis and the hard disk is fixed to the conductive chassis through the use of an insulating member, the method comprising:
in a state of applying a predetermined signal to wiring or a component in the hard disk, measuring common-mode current flowing through the interface cable and the power cable of the hard disk and potential of an enclosure of the hard disk.

2. The method of measuring unnecessary electromagnetic radiation according to claim 1, wherein timing for measuring the common-mode current is shifted from timing for measuring the potential of the enclosure of the hard disk.

3. The method of measuring unnecessary electromagnetic radiation according to claim 2, wherein the method comprises:
measuring one of the common-mode current and the potential of the enclosure of the hard disk;
changing the state of applying the predetermined signal to the wiring or the component in the hard disk;
setting again the state of applying the predetermined signal to the wiring or the component in the hard disk; and
measuring the other of the common-mode current and the potential of the enclosure of the hard disk.

4. The method of measuring unnecessary electromagnetic radiation according to claim 1, wherein timing for measuring the common-mode current coincides substantially with timing for measuring the potential of the enclosure of the hard disk.

5. The method of measuring unnecessary electromagnetic radiation according to claim 1, wherein in the state of applying the predetermined signal to the wiring or the component in the hard disk, the method comprises measuring the common-mode current flowing through the interface cable and the power cable of the hard disk and the potential of the enclosure of the hard disk.

6. An apparatus for measuring unnecessary electromagnetic radiation, comprising:
a conductive chassis;
a conductive setting jig for installing a hard disk drive in the chassis;
a power cable and an interface cable that are connected to the hard disk drive;
a coaxial connector connected to an end of the conductive chassis; and
a current probe for measuring common-mode current flowing through the interface cable and the power cable,
wherein an outer conductor of the coaxial connector is connected to the chassis,
an inner conductor of the coaxial connector is connected to the setting jig, and
the setting jig is constructed to be electrically connected to an enclosure of the hard disk drive to be measured.

7. The apparatus for measuring unnecessary electromagnetic radiation according to claim 6, wherein impedance of a transmission line in which the hard disk drive is a core wire and the chassis is the outer conductor lies within the range of 45 to 55 ohms.

8. The apparatus for measuring unnecessary electromagnetic radiation according to claim 6, wherein the connector is provided at a chassis located in a direction opposite to a direction where the cables of the hard disk come out and the chassis tapers down toward the connector.

9. A system for measuring unnecessary electromagnetic radiation having the apparatus for measuring unnecessary electromagnetic radiation according to claim 6, the system further comprising:
a spectrum analyzer connected to the coaxial connector and the current probe.
